(19) United States
(12) Patent Application Publication
(10) Pub. No.: US 2024/0355775 A1
(43) Pub. Date: Oct. 24, 2024

(54) Semiconductor wafer and (micro) transfer printing process

(71) Applicant: X-FAB Semiconductor Foundries GmbH, Erfurt (DE)

(72) Inventors: Ralf LERNER, Erfurt (DE); Niclas HEISE, Erfurt (DE)

(21) Appl. No.: 18/428,928

(22) Filed: Jan. 31, 2024

(30) Foreign Application Priority Data
Feb. 2, 2023 (DE) 10 2023 102 601.1

(51) Int. Cl. H01L 23/00

(52) U.S. Cl. CPC H01L 24/83; H01L 24/95; H01L 2224/8385; H01L 2224/95

(57) ABSTRACT

The invention involves a semiconductor wafer for a (micro) transfer printing process and the manufacture of such a wafer to enable a (micro) transfer printing process with increased adhesion of the semiconductor element (20) transferred or printed on a surface of a carrier substrate. This is achieved with the semiconductor wafer (2), which consists of one layer (31, 31′, 31″, 31*) with at least one functional frame (34, 34′, 34″, 34*). Located within this (34, 36a) is a bonding material (36, 39; 54, 55). The bonding material (36) within the functional frame (34, 36a) has an at least partially concave surface (38, 38′, 38″) for contacting an underside (22) of a printed or transferred semiconductor element (20, 40).

The invention involves a semiconductor wafer for a (micro) transfer printing (μTP) process and the manufacture of such a wafer to enable a (micro) transfer printing process with increased adhesion of the (semiconductor) components transferred or printed on a surface of a carrier substrate to the surface of the carrier substrate.

Various (micro) transfer printing processes are known from the state of the art.

US 2009/0294803 A1, DE 11 2011 101 135 T5 and U.S. Pat. No. 8,664,699 B2 have publicized a transfer printing process in which semiconductor components are transferred from a first semiconductor wafer to a new substrate (second semiconductor wafer) by means of an elastomer stamp. The components to be transferred are first masked and exposed by etching on the sides. During this etching step, etching is performed around the component except for tethers as predetermined breaking points. The next etching step is to etch off the area underneath the component. The components are held together mechanically by the tethers. Some of the etched-off components are brought into compliant contact with the surface of a stamp. The components may be detached from the first semiconductor wafer by adhesion to the stamp, whereby the tethers are broken. The components adhering to the stamp are then brought into compliant contact with the surface of a new substrate (second semiconductor wafer) and fixed in place there. The process makes it possible to simultaneously transfer a large number of components from a first semiconductor wafer to a second semiconductor wafer.

U.S. Pat. No. 7,932,123 B2 describes processes that make the functional structures printable by producing or using a large number of “release layers.”

U.S. Pat. No. 7,943,491 B2 and US 2013/0069275 A1 both describe a kinetically controlled process for adjusting the adhesion forces influenced by the separation speed between a component to be transferred and the transfer stamp. High adhesion forces are generated during fast separation (temporary attachment of components to the stamp), and components may be detached from the stamp again at low separation rates or low adhesion forces.

U.S. Pat. No. 7,799,699 B2 describes the etching off of AlGaN/GaN heterojunction components on (111) silicon. Suitable masking and vertical ICP (Inductive Coupled Plasma) etching are used to etch exposed, i.e., non-masked, trenches next to the component. In the horizontal direction, the components are exposed by etching the silicon substrate under the component using TMAH (tetramethylammonium hydroxide). Mechanical fixing is achieved in the horizontal direction by suitable interruptions in the trenches, i.e., by means of material tethers that are not etched away.

As a rule, components that are to be transferred or printed from one substrate to another in a (micro) transfer printing process are exposed by etching down to the tethers (as above) and thus prepared for the actual transfer printing step. Exposing by etching is carried out in two etching process steps: a first etching step perpendicular to the substrate surface (vertical) and a second etching step parallel to the substrate surface (horizontal). During the first step, the tethers are defined; in the second step, exposing by etching is carried out underneath the component to be transferred. During the second etching step, the removal of the material starts at the outer edges of the component to be exposed and progresses to the center of the component. However, a small amount of material is also removed from the actual component. This material removal is greatest at the edges (where etching is done the longest) and decreases toward the center of the component. Due to the process (and the grid structure of the material), the underside of the exposed component is not planar but—in the sectional view—slightly or roughly V-shaped. Therefore, when these components are being printed with a slight V-shape, only a small contact area is created, or the surface of the substrate on which printing is to take place must be mechanically deformed for full-surface contact, or the component must be pressed into the surface layer, which may cause unintentional damage to the carrier substrate and/or the component.

One task of the invention is to enable a (micro) transfer printing process with increased adhesion between an exposed, printed component and a carrier substrate, while at the same time maintaining low contact pressures.

The task is resolved by a semiconductor wafer according to claim 1, a process according to claim 17, a process according to claim 22, or a process according to claim 29.

A semiconductor wafer consists of a layer with at least one functional frame, e.g., as a frame-shaped elevation or as an edge region of a layer into which a depression is made. Within the at least one frame (i.e., in the frame) there is a bonding material, preferably an adhesive, which has an at least partially concave surface for the contacting of at least one surface section of a (semiconductor) component.

The frame may be used to frame a (small) partial area of the layer or to separate it from other areas of the layer that lie in the same plane as the partial area. In particular, any material that is located on (applied to) this partial area or is located within a volume of a 3D projection of this partial area in the positive z-direction is located “within” the frame, preferably in the form of a frame-shaped elevation. The frame may also be functionally regarded as an edge area of a layer into which a pit is made as a depression to hold the bonding material. We call it the “embedded frame” on the edge next to the depression.

The material within the frame of the layer may be a different material than that of the layer from which the functional frame was formed.

The layer with at least one frame may be close to the surface. In this context, close to the surface means that the layer forms the uppermost layer of the semiconductor wafer or is covered by at most two layers.

The semiconductor wafer may be a semi-finished product for a micro-transfer printing process or may be provided as a semi-finished product for a micro-transfer printing process.

The material may be part of a layer applied to the layer with the at least one frame.

In particular, the concave (curved inward—in the direction of the layer with the frame) surface of the bonding material within the frame may be designed for full-surface contacting of an underside of a transferred component.

The underside of the exposed component may be an uneven surface. In particular, uneven can mean that the surface has a slightly or roughly V-shaped surface (viewed in the 2D section) due to process-related factors. A pyramid shape is also possible (viewed in 3D). The underside of the component may accordingly be formed by flat partial surfaces (or surface sections) that are angled toward each other (or that can be circumscribed in this way).

The angle between the partial surfaces may be an obtuse angle, i.e., an angle between a right angle and a straight angle (90.0° to) 180.0°. In the case of a rectangular component, the underside will be pyramid-shaped. There would then be four partial areas designated as “uneven”. If the component has a rectangular shape, the pyramid shape will have a rectangular base.

The bonding material within the frame may consist of an organic material, preferably an organic material. In particular, “organic material” may refer to synthetic resins and plastics. The bonding material within the frame may preferably consist of an epoxy material or a polyimide or an adhesive layer.

The bonding material may be multi-layered. One of the layers may give shape to another of the layers. In particular, the oxide is able to provide the at least partially concave surface.

If there is oxide inside the frame, an additional adhesive layer may be applied to the oxide. For example, an organic material may be used for the adhesive, preferably an epoxy material, a polyamide, or an adhesive. A liquid aggregate form is also possible.

The bonding material within the frame may also be—i.e., consist of—the adhesive layer itself.

The bonding material within the frame may have a thickness of at least preferably between 0.2 μm and 3.0 μm, preferably between 0.5 μm and 2.0 μm, preferably if it is multi-layered and a carrier portion thereof imparts the shape and a uniform layer thickness assumes the adhesive function.

The at least partially concave surface may be axially symmetrical in cross-section in relation to an axis of symmetry. A vertex (or vertex line) of the concave surface may be spaced between 40 μm and 800 μm from an edge in the direction of the axis of symmetry. In other words, a non-square component may have a dimension of between 40 μm and 60 μm for the smaller side length and a dimension of between 400 μm and 800 μm for the larger side length.

If the bonding material is part of a layer applied to the layer with the frame-shaped elevation or the functional frame, the edge area of the material of the layer may have a turning line (3D; cf. turning point 2D—point on a function graph at which the graph changes its curvature behavior).

If the bonding material is separated from the same material outside the frame-shaped elevation by the frame-shaped elevation (the material was part of an applied layer), the edge may be determined by the material; i.e., in this case, the edge is formed as a line of points at which there is still material inside the elevation and that are farthest away from the partial area when viewed orthogonally to the partial area (z-direction).

The at least one frame as a frame-shaped elevation may have a rectangular basic shape. Alternatively, the frame-shaped elevation may have a polygonal shape. The basic shape of the frame as, say, a frame-shaped elevation may be adapted to the shape of the printed component that is intended to contact the concave surface. For a (slightly) V-shaped underside, the frame-shaped elevation should be rectangular, for example. If the surface of the component that is to be contacted is pyramidal, the frame-shaped elevation should be square, for example.

The shape of the printed component therefore determines the shape of its underside and thus the shape of the frame.

The at least one frame-shaped elevation may have at least one interruption. Preferably, the at least one frame-shaped elevation may have interruptions in each corner area of the frame-shaped elevation. A “corner area” may be an area of the frame-shaped elevation in which imaginary extensions of (at least) two non-parallel sides of the elevation meet and form an intersection. For example, a rectangular frame-shaped elevation would have four corner areas.

The at least one frame-shaped elevation may have at least one recess. Preferably, the at least one frame-shaped elevation has at least two opposing recesses. In particular, the recesses may be located in an outer edge or defined in outer sides of the frame-shaped elevation.

The at least one recess may have a polygonal basic shape.

The at least one functional frame may be dimensioned such that the concave surface within the frame is configured to contact at least two or four surface portions as the underside of the printed component, preferably with full-surface contact. It is this way in the first approach, as the real underside of a component for transfer printing does not have multiple flat sections that are exactly inclined toward each other, and the concave surface of the bonding material does not identically mirror the shape of the underside of the component to be printed on it. It is an approximation of two similar surfaces, which is why the phrase “in the first approach” is chosen here. Full-surface contact is achieved when the component to be printed is pressed onto and into the concave surface by applying force.

Mathematically speaking, “in the first approach” stands for a linear approximation: In the process, two curved surface contours are adapted to each other. The underside of the printing component may be approximated with multiple flat surface pieces. The at least partially concave surface of the bonding material is adapted to this geometric shape in the first approach. The result is an adaptation of two surfaces that requires at least less force, the aim of which is to produce a full-surface bond without exerting high force on the component to be printed, which would be required if the bonding material had a flat surface overall.

The frame may also be dimensioned in such a way that a large number of semiconductor components can be placed on the concave surface.

The at least one functional frame may have a length of between 800 μm and 1200 μm and a width of between 50 μm and 800 μm.

The at least one functional frame as a frame-shaped elevation may have a (tether) height of between 150.0 nm and 850.0 nm, preferably between 250.0 nm and 750.0 nm.

In this case, the height of the frame-shaped elevation may be measured as the distance between two (essentially) parallel planes: a first plane, which is stretched by a surface of the layer with the at least one frame-shaped elevation, and a second plane, which is stretched by the end faces of the cuboid tethers of the frame-shaped elevation.

The greater the tether heights of the frame-shaped elevation are designed, the more distant from the edge the apex of the concave surface may be.

The at least one frame-shaped elevation may have a tether width of between 25.0 nm and 3000.0 nm, preferably between 65.0 nm and 2000.0 nm, at least partially.

For example, in the event that the at least one frame-shaped elevation has a rectangular basic shape, the elevation will have four cuboid tethers, the four corner areas of which are bonded to each other.

The semiconductor wafer may have a large number of effective frames, into each of which material can be introduced. All surfaces within the (filler) material introduced into the frame may be at least partially concave, with each forming an area for contacting an underside of the transferred component.

A process for manufacturing a semiconductor wafer (as a semi-finished product for a micro transfer printing process) consists of providing a semiconductor wafer with at least one functional frame protruding from a (topmost) layer of the semiconductor wafer or formed by a depression in a layer as its remaining edge portion. A layer serving as an adhesive layer is applied to a surface of the layer from which the at least one frame-shaped elevation protrudes. An area of the applied adhesive layer within the at least one frame-shaped elevation forms an at least partially concave surface for contacting an underside of a semiconductor component.

The semiconductor wafer provided for the process may be manufactured in a pre-structuring process. The pre-structuring process may produce a semiconductor wafer with structured layers (typical structured layers in wafer fabrication: Si3N4, Si2O3, polysilicon, metal).

The pre-structuring process may consist of the following: a layer deposition in the semiconductor process (CVD or PVD process/sputtering) on a (silicon) wafer as a carrier substrate or semiconductor wafer, an application of a masking layer that defines the basic shape (surface area) of the at least one frame-shaped elevation, an etching step to expose the at least one frame-shaped elevation, and a step in which the masking layer (e.g., photoresist) is removed (remover, stripping, etc.).

The masking layer may be produced using photolithographic processes (coating, exposure, etc.). The masking layer may be used as an etching mask.

The etching step may involve anisotropic etching.

The adhesive layer (layer serving as an adhesive) may consist of an organic material, preferably consisting of an organic material. In particular, the organic material may consist of or be an epoxy material or a polyimide or an adhesive layer.

The adhesive layer may be applied to the top layer of the semiconductor wafer by spin-coating.

The layer of adhesive within the frame-shaped elevation may have a thickness of between 0.2 μm and 3.0 μm, at least partially, preferably between 0.5 μm and 2.0 μm.

The concave surface of the layer of adhesive within the frame may be axially symmetrical in cross-section in relation to an axis of symmetry, and an apex of the concave surface is spaced from an edge in the direction of the axis of symmetry.

In particular, the at least one frame-shaped elevation in the uppermost layer of the semiconductor wafer provided for the process may have at least one feature, a combination of features, or all features of the features described above with reference to the frame-shaped elevation (with regard to the dimensioning, design, etc.).

A process for manufacturing a semiconductor wafer (as a semi-finished product for a micro transfer printing process) consists of providing a semiconductor wafer with at least one functional frame formed from a first (uppermost) layer of the semiconductor wafer, applying a second layer to a surface of the first layer from which the at least one frame-shaped elevation protrudes, and overpolishing the applied second layer, whereby a region of the second layer within the frame-shaped elevation has at least a partially concave surface for contacting an underside of a semiconductor device.

Overpolishing usually refers to the unwanted removal of material that occurs during (chemical-mechanical) polishing (CMP) of wafer surfaces. During (accidental) overpolishing, a concave curved surface is usually formed in the overpolished material; see Pic, Nicolas & Bennedine, Karim & Tas, Guray & Alliata, Dario & Clerico, Jana. (2007). Characterization of Copper Line Array Erosion with Picosecond Ultrasonics. 931.10.1063/1.2799398 or Lai, Jiun-Yu & Saka, Nannaji & Chun, Jung-Hoon. (2002). Evolution of Copper-Oxide Damascene Structures in Chemical Mechanical Polishing I. Contact Mechanics Modeling. Journal of The Electrochemical Society—J ELECTROCHEM SOC. 149.10.1149/1.1420708. This effect can be desired or utilized here to generate a concave surface with a certain degree of curvature.

When the second applied layer is being overpolished, polishing may continue until one surface (end face) of the frame-shaped elevation is completely exposed. In this case, (minimal) removal may take place not only on the second layer but also on the frame-shaped elevation of the first layer. In the process, material of the second layer may be separated from the remaining second layer, or material inside the frame-shaped elevation will no longer be bonded to the remaining second layer outside the frame-shaped elevation. Removal (or removal rate) due to overpolishing may be greater, in particular on material of the second layer, than removal on the frame-shaped elevation of the first layer.

The second layer may consist of an oxide layer, preferably an oxide layer.

The oxide layer may be formed by thermal oxidation, for example.

Overpolishing may involve chemical-mechanical polishing.

Moreover, following overpolishing, the process may also involve the application of a third layer serving as an adhesive layer. If (over) polishing is not carried out up to the frame-shaped elevation, the third layer serving as an adhesive is applied exclusively to the second layer. In the event that the surface (end face) of the frame-shaped elevation is exposed by (over) polishing, the third layer will partially cover material of the second layer and the exposed surface of the frame-shaped elevation of the first layer.

The third layer serving as an adhesive (adhesive layer) may have a thickness of between 20.0 nm and 1000.0 nm, preferably between 50.0 nm and 500.0 nm.

The material of the overpolished second layer within the frame-shaped elevation together with the adhesive layer may have a thickness of between 0.2 μm and 4.0 μm, at least partially, preferably between 0.5 μm and 2.5 μm.

The concave surface may be axially symmetrical in cross-section in relation to an axis of symmetry (A), and an apex of concave surface (38) may be spaced between 140.0 nm and 840.0 nm, preferably between 240.0 nm and 740.0 nm, from an edge in the direction of the axis of symmetry.

In particular, the at least one frame-shaped elevation in the first layer of the semiconductor wafer provided in the process may have at least one feature, a combination of features, or all features of the features described above with reference to the frame-shaped elevation (with regard to the dimensioning, design, etc.).

A transfer printing process involves providing a first semiconductor wafer with semiconductor components, providing a second semiconductor wafer, and transferring at least one component from the first semiconductor wafer to the second semiconductor wafer in a transfer printing step. The at least one component is transferred and printed on a concave surface within a functional frame of the second semiconductor wafer.

Furthermore, the transfer printing process may also involve detecting a position of the at least one frame-shaped elevation on the semiconductor wafer by means of recesses in a frame-shaped elevation. In particular, recognizing the position of a frame-shaped elevation on the second semiconductor wafer may be used for precise placement of a semiconductor device on the concave surface within the frame-shaped elevation.

The transfer printing process may also be used to print two components on a concave surface within the frame-shaped elevation.

In the transfer printing process, a large number of components can be transferred from the first semiconductor wafer to the second semiconductor wafer; in particular, one component may be transferred to each concave surface within a functional frame. The contact pressure or press-in pressure used on the component may be lower—as if the concave surface of the bonding material were not present. The approximation of this curved surface to the multiple flat partial surfaces of the underside of the component enables this favored force or pressure situation.

The embodiments of the invention are explained by means of examples, but not in such a way that limitations from the figures or more specific forms are (to be) read into the patent claims as long as these limitations or concretizations are not included there. Identical reference signs in the figures indicate identical elements.

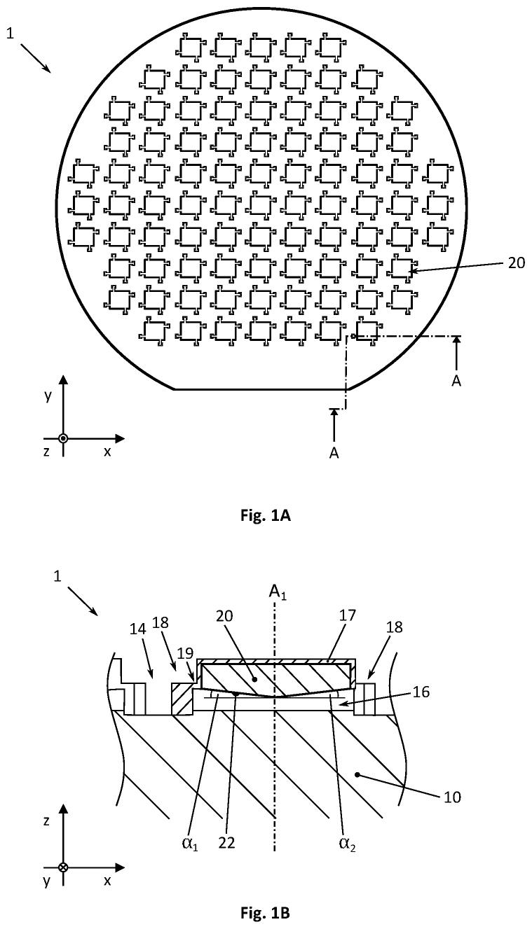

FIG. 1A shows a first semiconductor wafer 1 with (semiconductor) components 20 in a schematic top view;

FIG. 1B shows a schematic sectional view A-A of a component 20 on first semiconductor wafer 1;

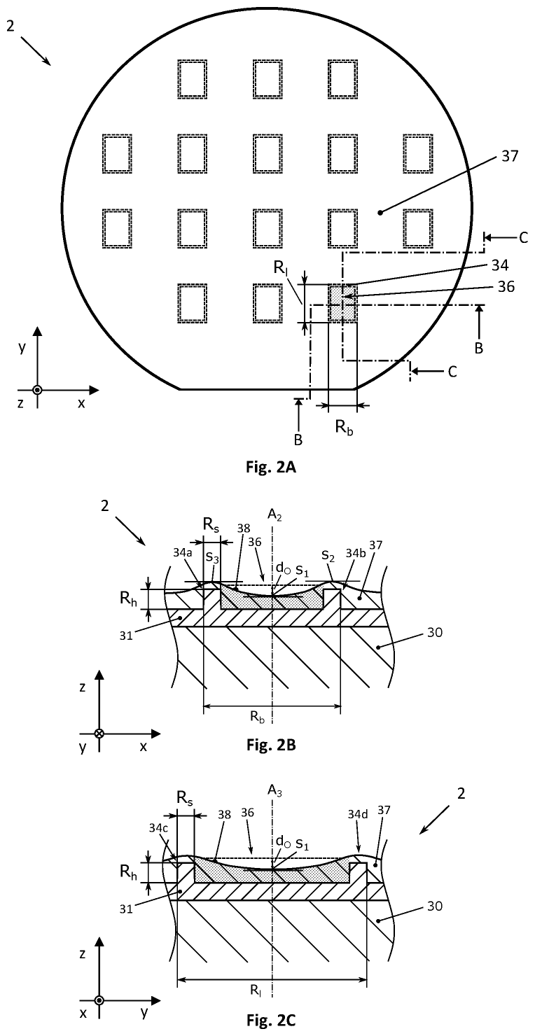

FIG. 2A shows a second semiconductor wafer 2 with frame-shaped elevations 34 coated with a layer 37 in a schematic top view;

FIG. 2B shows a schematic sectional view B-B through one of frame-shaped elevations 34 of second semiconductor wafer 2 of FIG. 2A;

FIG. 2C shows a schematic sectional view C-C through one frame-shaped elevation 34 of second semiconductor wafer 2 of FIG. 2A;

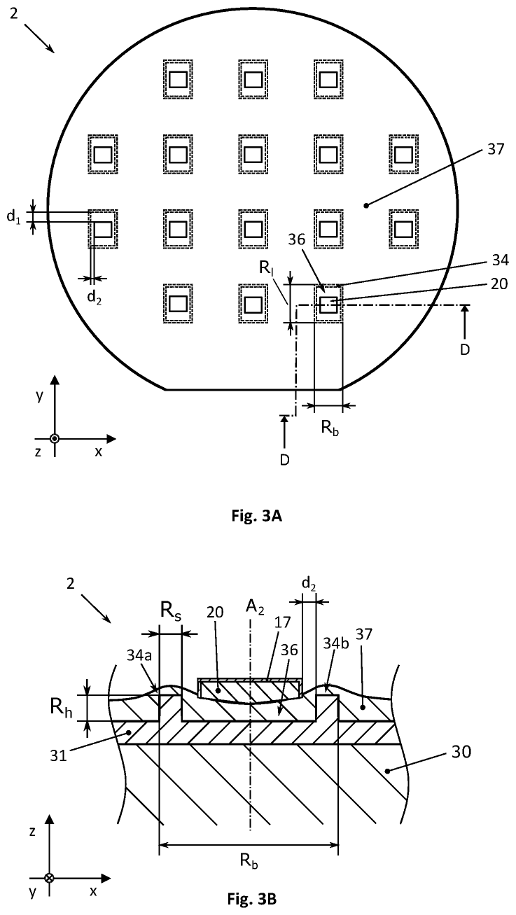

FIG. 3A shows second semiconductor wafer 2 with printed (semiconductor) components 20 within frame-shaped elevations 34 in a schematic top view;

FIG. 3B shows a schematic sectional view D-D through one of frame-shaped elevations 34 with printed component 20 from FIG. 3A;

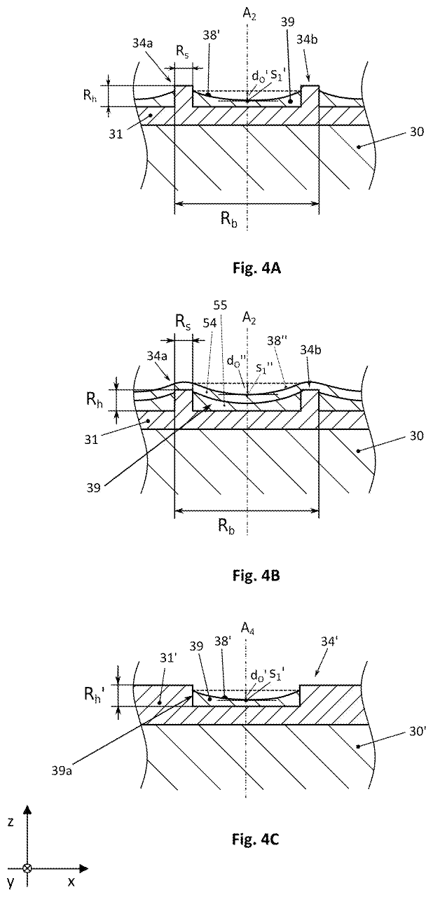

FIG. 4A to 4C show additional embodiments of a surface of second semiconductor wafer 2 in sectional views.

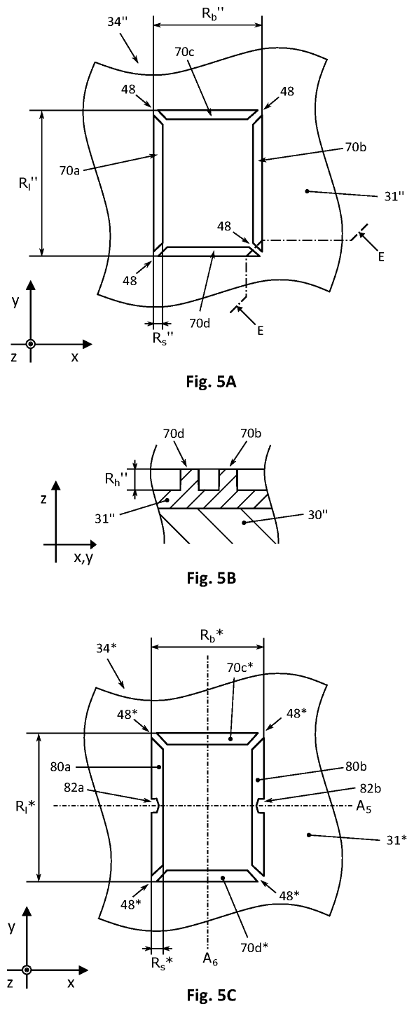

FIG. 5A shows another embodiment of a frame-shaped elevation 34″ in a schematic top view;

FIG. 5B shows a schematic sectional view E-E through frame-shaped elevation 34″ of FIG. 5A; and

FIG. 5C shows another embodiment of a frame-shaped elevation 34*′ in a schematic top view.

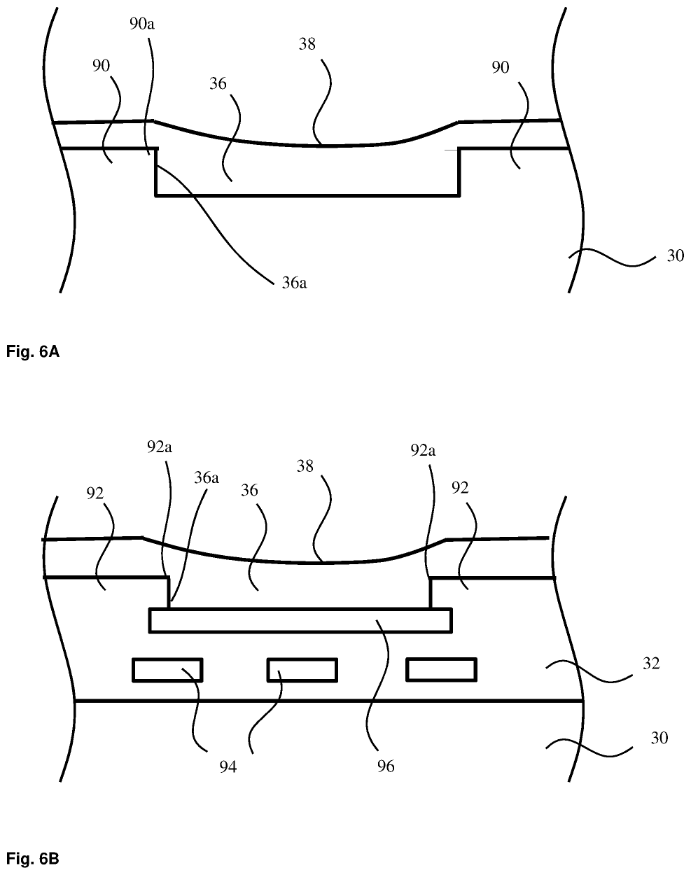

FIG. 6A illustrates a simplified variant in which the frame-shaped elevation is functionally formed by the remaining material at edge 90a of a pit 36a etched into the semiconductor (filled with bonding layer 36).

FIG. 6B shows the sectional view of the pit etched into the BEOLD, such as stopping on a metal layer 96. The frame is formed by the remaining ILD material on the edge at 92a. The depression here is also 36a, filled with bonding layer 36.

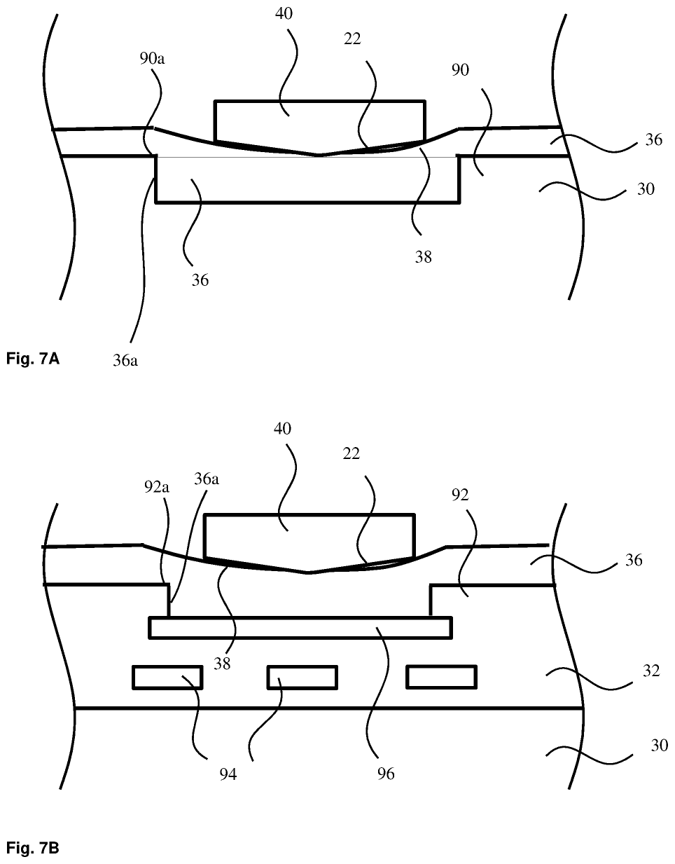

FIG. 7A illustrates a combination of FIG. 6A with the previously described embodiment of the placement of a printed component 20 from FIG. 3A, labeled here as 40.

FIG. 7B illustrates a combination of FIG. 6B with the previously described embodiment of the placement of printed component 40 from FIG. 3A.

FIG. 1A shows a first semiconductor wafer 1 in a schematic top view. A large number of semiconductor components 20 (components for short) are located on the first semiconductor wafer. Semiconductor components 20 are arranged in a grid on first semiconductor wafer 1. The coordinates or positions of semiconductor components 20 can be clearly determined on the first semiconductor wafer by means of an x/y coordinate system. The coordinate system lies in a plane congruent with the plane that is spanned by a surface of the first semiconductor wafer 1 (front side).

In this example, first semiconductor wafer 1 has a circular basic shape from which a partial (“flat”) segment is cut off, thereby creating a straight edge. The semiconductor wafer may also have a “notch”-then without a straight edge piece (not shown).

Components 20 on the first semiconductor wafer may consist of integrated circuits or be micromechanical components. The semiconductor components may be functional components. In this context, functional can mean that components 20 are useful for their assigned function. For example, they may be exposed to transfer printing (removed from carrier 1 and placed on carrier 2).

FIG. 1B shows a schematic sectional view A-A (see FIG. 1A) of first semiconductor wafer 1. Component 20 may consist of a structured stack (structuring and layers not shown). Component 20 is partially enclosed by a layer 17. Depending on the process, layer 17 covers all but one surface of component 20. This underside 22 faces the substrate of the semiconductor wafer.

Underside 22 may be formed from multiple contiguous partial surfaces.

If component 20 consists of several layers, underside 22, which is not covered by layer 17, may be the surface of a lowermost layer of component 20.

Layer 17 is preferably a polymer layer.

Underside 22 may be flat. However, the process may result in underside 22 not being flat or only partially flat, as shown (at an angle) in the figure.

In the sectional view, underside 22 has two (flat) partial surfaces that enclose an obtuse angle, meaning that underside 22 is slightly V-shaped in cross-section. An (acute) angle α₁ and α₂ is included between a plane parallel to an x-direction through a vertex (2D sectional view; 3D vertex line) of underside 22 and one of the partial surfaces of underside 22 in each instance.

Angles α₁ and α₂ may be the same, as shown, or different.

The reproduction of the underside using the two flat partial surfaces in the sectional view is an approximation. Bringing about the separation of the components to be printed can also result in a slightly curved underside, or in four inclined partial surfaces with a pyramid shape, each of which is flat in the first approach yet already has a slight degree of curvature arising from the practical production process.

Component 20 is axially symmetrical to axis A₁. The axis is parallel to the z-direction. The xy plane is defined by semiconductor wafer 1, with z describing a direction perpendicular to it.

Component 20 is separated by a first trench 14 from other semiconductor components 20 on first semiconductor wafer 1 as viewed in the x/y-direction. First trench 14 can be produced by a vertical etching step (in the z-direction). On the semiconductor wafer, the etching extends in the x/y-direction.

Layer 17 is bonded to a surface of the carrier substrate 10 via tethers 18. Tethers 18 hold component 20 at a distance from the surface of carrier substrate 10 when viewed in the z-direction, or there is a second trench 16 between semiconductor component 20 and the surface of carrier substrate 10. Second trench 16 can be produced by a horizontal (along the x-direction) etching step.

Component 20 is mechanically held exclusively by layer 17 with tethers 18.

Tethers 18 each have a thinned area 19 that serves as a predetermined breaking point.

FIG. 2A shows a second semiconductor wafer 2 with frame-shaped elevations 34 here, which are coated with a layer 37. Accordingly, the positions/dimensions of the frame-shaped elevations are only indicated in the schematic plan view (dashed lines).

Frame-shaped elevations 34 of second semiconductor wafer 2 are identical to one another. Alternatively, frame-shaped elevations 34 may be different from one another or be dimensioned to correspond to the shape of component 20.

Elevations 34 may also be represented as a frame embedded in the disk, which is defined by the recess and is nevertheless to be designated as a functional frame, in consideration of the effect of the edge areas of the material left outside the depression.

The term “elevation 34” will only be used as an example in the rest of the description where the frames are also shown as elevated. FIG. 4C, for example, is also provided with an “embedded frame,” which is defined by the depression located inside (in which material 36 of spin-coated layer 37 is held). Functionally, it corresponds to edge area 90a of FIG. 6A (as non-etched portion 90a or 92a of the substrate (90 or 92) of FIG. 7B). In these examples, there is no longer a separate physical frame; instead, it is functionally replaced or formed by the edge area of the non-recessed substrate, which is why it should be called the “embedded frame.” The depression is 36a in both FIGS. 6A and 7A, each filled with bonding material 36.

In FIG. 2A, dimensions are shown by means of a frame-shaped elevation 34 on first semiconductor wafer 2 as representative of all frames, which are called frames here and may also be formed in a complementary manner by forming a depression within the embedded frame. This is the embedded frame or the effective frame, as shown in FIG. 6A, 7A, or 4C, for example.

Frame 34 has length Rₗ and width R_{w}. Length Rₗ and width R_{w} refer in each case to outer (more distant) side surfaces of frame 34 viewed with respect to an axis of symmetry A₂ and A₃, respectively. For reasons of clarity, symmetry axes A₂ and A₃ of the frame are shown in FIGS. 2B and 2C.

Both length Rₗ and width R_{w} of frame 34 may be between 25 μm and 1000 μm, preferably between 50.0 μm and 500.0 μm. Typically, the dimensions for width and length are between 1000 μm and 100.0 μm for the component to be transferred.

FIG. 2B shows a schematic sectional view B-B (cf. FIG. 2A) through frame 34 on the second semiconductor wafer. Frame 34 is part of a layer 31, which is applied to a carrier substrate 30. Layer 31 may in turn be part of a (metallization) stack. In addition to layer 31, the stack may also contain other structured layers (structuring and other layers are not shown).

In the example in FIG. 2B, the frame is an elevation 34.

The frame as a frame-shaped elevation 34 has four cuboid tethers 34a to 34d, which are bonded to each other via corner areas of the frame-shaped elevation. Tethers 34a to 34d each have a height Rₕ, which may be done in two ways; they protrude from layer 31 with height Rₕ, or they are in layer 31 by the frames being etched free from the disk or layer 31 (not shown in the illustration).

The height of tethers Rₕ may be between 150.0 nm and 850.0 nm, preferably between 250.0 nm and 750.0 nm. Tethers 34a to 34d may also have different tether heights in relation to one another.

Four cuboid tethers (as frame pieces) 34a to 34d each have a tether width Rₜ. Tether width Rₜ may be between 25.0 nm and 3000.0 nm, preferably between 65.0 nm and 2000.0 nm. Tethers 34a to 34d may also have different tether heights in relation to one another.

Layer 31 with frame-shaped (relative) elevation 34 carries additional layer 37. Additional layer 37 may be a layer serving as an adhesive. Preferably, layer 37 consists of an organic material, such as an epoxy material, a polyimide, or an adhesive. For example, the adhesive may be a self-curing adhesive capable of curing after printed component 20 has been placed on it in order to permanently bond component 20 to carrier substrate 2 or 30. The same applies to adhesive 36 in FIGS. 6A and 7A.

Layer 37 may be applied by spin-coating it onto a surface of layer 31 with frame-shaped elevation 34. Due to the process and material, when liquid substances are applied, such as photoresist, polyimide, or epoxy materials or other organic liquids serving as an adhesive layer, the thickness of layer 37 applied by means of spin-coating will become thicker in the vicinity of frame-shaped elevation 34 than in areas farther away from the frame-shaped elevation, whereby bonding material 36 of applied layer 37 forms a concave surface 38 within frame-shaped elevation 34 (at least partially).

This also applies to the variant with the functional frame—as an embedded frame—which is formed by the depression inside by the layer left on the edge.

Bonding material 36 within frame-shaped elevation 34 may refer to any material that is applied within frame-shaped elevation 34 in the positive z-direction on a partial surface separated by frame-shaped elevation 34. This is illustrated by a shading of corresponding material 36 of layer 37 in FIGS. 2A to 2C.

Both height Rₕ and width R_{w}, length Rₗ and the tether width Rₜ of the frame-shaped elevation may be adapted to component 20, i.e., to a corresponding underside 22 of component 20 that is to be contacted. For example, if an underside 22 of a semiconductor component 20 that is to be contacted has a more acute (but still obtuse) angle, height Rₕ of tethers 34a to 34d may be increased accordingly so that applied bonding material 36 of adhesive layer 37 has a greater curvature within frame-shaped elevation 34.

The preferred frame dimensions (height Rₕ, width R_{w}, length Rₗ, tether width Rₜ) are such that the partial area within the frame-shaped elevation is greater than that of a component 20 to be held. The semiconductor component may also have one dimension in common with the frame. For example, an outer contour of component 20 may overlap with an inner edge of frame-shaped elevation 34 after being applied.

Concave surface 38 is (practically) axially symmetrical to axis A₂. If frame-shaped elevation 34 is axially symmetrical to axis A₂, as shown in FIG. 2A, concave curved surface 38 of bonding material 36 within the frame-shaped elevation will also be (practically) axially symmetrical (A₂, A₃).

Concave surface 38 has two turning points in the sectional view (2D). When viewed in three dimensions, concave surface 38 will have a “turning line.” This turning line may be regarded as the edge of the concave curvature of surface 38 within frame-shaped elevation 34. Two points on this edge are shown in the sectional view as intersections of a dashed line with concave surface 38. The distance from the edge (of the concave curvature) to an apex a₁ of concave surface 38 is marked as dₒ.

This dimension dₒ can be used to define the degree of curvature of the concave surface. It is based on the inclination of the multiple partial surfaces of the underside of the components. A greater inclination, i.e., larger angles α from FIG. 1B, will also require a larger dimension dₒ.

The apex of concave surface 38 can be as far away from the edge in the direction of axis of symmetry A₂ as tether height Rₕ of frame-shaped elevation 34.

A ratio dₒ/Rₕ of apex distance dₒ to the edge and tether height Rₕ may be between 0.50 and 0.98, preferably between 0.60 and 0.90.

In the sectional view, additional layer 37 also has vertices v₂ and v₃ in areas in which layer 37 covers tethers 34a and 34b. The frame-covering areas of layer 37 have a concave curvature (at least partially). Vertices v₂ and v₃ are (substantially) equidistant from a surface of frame-shaped elevation 34 (viewed in the z-direction).

The distance between apex a₁ to the apex/apices a₂ and/or a₃ may be greater than tether height Rₕ of frame-shaped elevation 34.

The distance between a₁ and a₂ as well as the distance between a₁ and a₃ may be the same (as shown).

FIG. 2C shows a schematic sectional view C-C (cf. FIG. 2A) through frame-shaped elevation 34 of second semiconductor wafer 2 viewed from a different direction.

The frame-shaped elevation is axially symmetrical to axis A₃. In this view, in particular tethers 34c and 34d are visible, as is length Rₗ of frame-shaped elevation 34.

FIG. 3A shows second semiconductor wafer 2 with printed components 20 within frame-shaped elevations 34 in a schematic top view.

Components 20 may be transferred from first semiconductor wafer 1 to second semiconductor wafer 2 using one or more transfer printing processes. A transfer may be carried out using an (elastomer) stamp, for example. When components 20 are detached from first semiconductor wafer 1, particularly areas 19 defined as predetermined breaking points may break, and tethers 18 may remain on the first semiconductor wafer. Remaining layer 17 without tethers 18 may be transferred together with component 20 to the second conductor disk, as shown in FIG. 3B.

Components 20 are located in the center of frame 34.

A first distance d₁ between the side surfaces of semiconductor components 20 and tethers 34c and 34d (y-direction) may be the same in each instance. A second distance d₂ between the side surfaces of semiconductor components 20 and tethers 34a and 34b (x-direction) may be the same.

First distance d₁ is greater than second distance d₂.

FIG. 3B shows a schematic sectional view D-D (cf. FIG. 3A) through frame-shaped elevation 34 with printed component 20.

Due to concave surface 38 of layer 37 (serving as an adhesive), a lower contact pressure is needed to produce a largely full-surface contact between underside 22 with its partial surfaces of component 20 and concave surface 38—adapted to the former in the first approach—than if (non-flat) underside 22 of component 20 has to be brought into full-surface (form-fit) contact with a flat surface on second semiconductor wafer 2. This reduces the risk of mechanical damage.

Remaining layer 17 on transferred semiconductor device 20 may be removed in an additional process step.

FIGS. 4A to 4C show additional embodiments of a surface of second semiconductor wafer 2 in sectional views.

FIG. 4A shows frame-shaped elevation 34 from FIGS. 2B and 3B.

Bonding material 39 is located within frame-shaped elevation 34 and has a concave surface 38′, which corresponds to concave surfaces 38 for bonding an underside 22 of a component 20.

Bonding material 39 may be an organic material. In this case, the material can be applied to the surface of second semiconductor wafer 2 by spin-coating. In contrast to FIG. 2A, the spin-coating can be ended earlier, thereby applying less bonding material 39 within frame-shaped elevation 34. A thin (50.0 nm to 500.0 nm) layer of the spin-coated material can also be applied to frame-shaped elevation 34 (not shown).

Bonding material 39 may contain an oxide. The curvature of concave surface 38′ can be produced by overpolishing (chemical-mechanical polishing) of the oxide. Bonding material 39 may have been part of an oxide layer before overpolishing.

The same material as bonding material 39 inside elevation 34 is also located outside frame-shaped elevation 34 on layer 31. Bonding material 39 is separated from the material applied outside elevation 34 by elevation 34 or is not bonded to it.

Concave surface 38′ is axially symmetrical to axis A₂ and has an apex a₁′. There are no turning points (turning lines) in this configuration. Bonding material 39 is separated from material outside frame-shaped elevation 34 by frame-shaped elevation 34. In this case, an edge of surface 38′ is formed as a line of points at which there is still material inside the elevation and that are farthest away from a (partial) surface within frame-shaped elevation 34 (z-direction). In the sectional view, two points of the (material) edge are shown as intersections between a horizontal (parallel to the x-axis) dashed line and concave surface 38′ of material 39 within frame-shaped elevation 34.

A Distance dₒ′ cannot be the same as or similar (+10.0%) to distance dₒ.

An apex a₁′ of concave surface 38′ may be equal to a₁.

A ratio dₒ′/Rₕ of apex distance dₒ′ to the edge and tether height Rₕ′ may be between the same as or similar to ratio dₒ/Rₕ.

In FIG. 4B, bonding material 39 is formed in multiple layers within frame-shaped elevation 34, with an additional layer 54 being applied to frame-shaped elevation 34 and a lower layer 55. The shape of the surface is determined by lower layer 55, which is covered with additional layer 54 and provides the at least partially concave surface. It may be formed by an oxide that has been given its surface geometry in a chemical-mechanical polishing step.

Layer 54 may have a (substantially) homogeneous thickness. The thickness of adhesive layer 54 may be between 20.0 nm and 1000.0 nm, preferably between 50.0 nm and 500.0 nm.

Bonding material 39 (the sum of the layers in the frame) may contain an oxide. Layer 54 may be a layer acting as an adhesive. Adhesive layer 54 and the lower layer 55 form “bonding material 39,” which in this case is multi-layered. Lower layer 55 forms the shape of the concave surface, and, while adhesive layer 54 adapts to this shape, it does not itself have the thickness to determine the shape.

Together with the oxide layer, bonding material 39 defines the concave curvature in surface 38″ of layer 54 (preferably serving as an adhesive). Surface 38″ corresponds to concave surfaces 38 and 38′.

Since second layer 55 already defines the concave curvature of surface 38″ (or concave surface 38′), layer 54 may be applied as a thin uniform layer (50.0 nm to 500.0 nm). Layer 54 has an apex a₁″.

Apex distance dₒ″ may be measured at one edge of the concave curvature of surface 38″. Analogous to FIG. 2B, FIG. 4B shows two edge points of the concave curvature—as intersections of a dashed line with surface 38″ of layer 54.

Apex distance dₒ″ corresponds to apex distances dₒ and dₒ′.

FIG. 4C shows yet another embodiment example, here as a functional frame 34′. Frame 34′ is a portion of a layer 31′, which is applied to a carrier substrate 30′. Layer 31′ may in turn be part of a (metallization) stack. In addition to layer 31′, the stack may also contain other structured layers (structuring and other layers are not shown).

Frame 34′ is axially symmetrical to axis A₄.

Compared to frame-shaped elevation 34, frame 34′ has a (significantly) larger “tether width.” Due to the way in which this embedded frame is formed, it is no longer possible to speak of a tether width, as there is a depression 39a in layer 31′ (an “embedded” frame lying around the depression, or edge area 34′ of layer 31′). Also in this example, frame 34′ can be formed by lowering 39a (formation of the depression) of the area within, whereby frame 34′ is embedded in layer 31′ (conceptually assumed and functionally realized).

Bonding material 39, which has concave surface 38′, is inserted inside frame 34′. Concave surface 38′ is axially symmetrical to axis A₄.

Functional frame 34′ has a height Rn′ and corresponds to layer thickness 31′ in the example. Height Rₕ′ may be the same as or similar to Rₕ.

FIG. 5A shows a partial section of a semiconductor wafer with a frame-shaped elevation 34″ in a schematic top view, which protrudes from a layer 31″.

Frame-shaped elevation 34″ is divided into four sections, tethers 70a to 70d, which are not bonded to one another but are separated from one another by interruptions 48. Interruptions 48 are located in (corner) areas in which cuboid tethers 70a to 70d would form a corner or an edge if they were bonded to one another.

Tethers 70a and 70b are parallel to each other (y-direction), and tethers 70c and 70d are parallel to each other (x-direction).

Tethers 70a to 70d may be cuboid. The cross-section of tethers 70a to 70d may be rectangular.

Tethers 70a to 70d have tether width Rₜ “, which may be the same as or similar to Rₜ.

Tethers 70a to 70b have tether length RI”, which may be the same as or similar to RI.

Tethers 70c to 70d have width R_{w} “, which may be the same as or similar to R_{w}.

FIG. 5B shows a sectional view E-E (cf. FIG. 5A) of frame-shaped elevation 34” from FIG. 5A.

Tethers 70a to 70d protrude from layer 31″, which is the same as or similar to layer 31.

Tethers 70d and 70b each have a tether height Rₕ “. All tethers 70a to 70d may have height Rₕ”, which is the same as or similar to Rₕ.

Layer 31″ is located on a carrier substrate 30″. Carrier substrate 30″ may be the same as carrier substrate 30.

Due to interruptions 48 in frame-shaped elevation 34″ (or between tethers 70a to 70d), excessive curvature when applying an additional layer by means of spin-coating to the surface of layer 31″ may be avoided with frame-shaped elevation 34″, such as a layer serving as an adhesive.

FIG. 5C shows a partial section of a semiconductor wafer with a frame-shaped elevation 34* protruding from a layer 31″ in a schematic top view.

Frame-shaped elevation 34* is divided into four sections, tethers 80a to 80b, 70c*, and 70d*, which are not bonded to one another but are separated from one another by interruptions 48*. Interruptions 48* are located in (corner) areas in which cuboid tethers 80a, 80b, 70c*, 70d* would form a corner or at least an edge if they were bonded to one another. Tethers 70c* and 70d* may be the same as tethers 70c and 70d. Interruptions 48* may be the same as the interruptions 48.

Tethers 70c* and 70d* are parallel to each other (y-direction), and tethers 80a and 80b are parallel to each other (x-direction).

Tethers 80a to 80b may be at least partially cuboid. The cross-section of tethers 80a to 80b may be at least partially rectangular.

Tethers 80a to 80b have tether width Rₜ*, which may be the same as or similar to Rₜ.

Tethers 80c to 80d have tether length RI*, which may be the same as or similar to RI.

Tethers 70c* to 70d* have width R_{w}*, which may be the same as or similar to R_{w}.

Tethers 70c* to 70d* may have height Rₕ*, which may be the same as or similar to Rₕ.

Tethers 80a, 80b, 70c*, 70d* may protrude from a layer that may be the same as or similar to layer 31 (not shown). The layer from which tethers 80a, 80b, 70c*, and 70d* protrude may be located on a carrier substrate.

Tethers 80a, 80b, 70c*, and 70d* may each have a tether height that is the same as or similar to Rₕ.

Layer 31″ is located on a carrier substrate 30″. Carrier substrate 30″ may be the same as carrier substrate 30.

Recesses 82a and 82b are located in tethers 80a and 80b. The recesses are axially symmetrical to an axis of symmetry A₅ (x-direction). Recesses 82a and 82b are axially symmetrical to an axis of symmetry A₆ (y-direction).

Recesses 82a and 82b are defined in outer sides or in side surfaces of tethers 82a and 82b located further out, viewed with respect to axis A₆.

Recesses 82a and 82b may serve as position markers.

Recesses 82a and 82b may have a basic shape that is (significantly) different from other typical geometric structural features on a circuit. For example, this may make it easier for an optical recognition system to distinguish between a conducting channel and recesses 82a and 82b serving as position markers.

Recesses 82a and 82b may have a polygonal, non-circular, and/or round basic shape.

In particular, if recesses 82a and 82b serving as position marks are provided in a frame-shaped elevation 34* (alternatively, also in webs 34a to 34d of a frame-shaped elevation 34 without interruptions 48 in corner regions), a process step may take place in which one or more layer(s) covering the elevation are at least partially removed, thereby causing recesses 82a and 82b serving as position marks to be exposed for optical recognition.

In FIG. 6A, previously described frame 34 is formed by the remaining substrate material-functionally and structurally-which corresponds to edge region 90a of each pit 36a introduced into substrate 30. The reference signs from the previous examples can be applied to this example. The spin-coated bonding material 36, which may be in the form of an adhesive, forms surface curvature 38 of the adhesive layer. Since there are no raised frames corresponding to physical frame 34 here, spin-coated layer 37 is not present, but instead adhesive layer 36 introduced into pit 36a as such. There is therefore no separation by the frame, which creates a separation between entire layer 37 and bonding layer 36 inside the frame.

In FIG. 6B, pit 36a has been etched into the BEOL ILD (Layer-Di-electric) and stops on a metal layer 96 during etching. Here, too, the frame is functionally the material 92a left on the edge of the pit.

Additional metal layers are labeled 94, 96.

FIGS. 7A and 7B correspond to the placement of printed component 20 from FIG. 3B, in conjunction with FIG. 6A and FIG. 6B, respectively. The printed component is labeled 40 here.

It can be seen in the sectional views that the adaptation of underside 22 of components 40 to concave section 38 of the upper side is possible in the first approach, since the real underside of a component 40 for transfer printing does not have multiple flat sections that are inclined exactly toward each other. And concave surface 38 of bonding material 36 does not identically mirror the shape of the underside of component 40 to be printed on it.

It is an approximation of two similar surfaces, which is why the phrase “in the first approach” is chosen here. Full-surface contact is achieved when the component to be printed is pressed onto and into the concave surface by applying force.

Mathematically speaking, “in the first approach” stands for a linear approximation: In the process, two curved surface contours are adapted to each other. The underside of the printing component may be approximated with multiple flat surface pieces. The at least partially concave surface of bonding material 36 is adapted to this geometric shape in the first approach. The result is an adaptation of two surfaces that requires at least less force, the aim of which is to produce a full-surface bond without exerting high force on the component to be printed, which would be required if the bonding material had a flat surface overall.

1. Semiconductor wafer, consisting of
one layer (31, 31′, 31″, 31*) with at least one functional frame (34, 34′, 34″, 34*), whereby a bonding material (36, 39; 54, 55) is located within the frame (34);
whereby the bonding material (36, 39) within the functional frame (34) has an at least partially concave surface (38, 38′, 38″) for contacting an underside (22) of a printed or transferred semiconductor element (20).

2. Semiconductor wafer (2) according to claim 1, whereby the bonding material (36) consists of an organic material, preferably an epoxy material, polyimide, or an adhesive.

3. Semiconductor wafer (2) according to claim 1, whereby the bonding material (39) is multilayer (54, 55).

4. Semiconductor wafer (2) according to claim 3, whereby a layer (54) acting as an adhesive is applied to an oxide (55) in the bonding material (36) within the frame (34); in particular, the oxide at least partially forms the concave surface.

5. Semiconductor wafer (2) according to one of the preceding claims, whereby the bonding material (36) has a thickness at least partially between 0.2 μm and 3.0 μm, preferably between 0.5 μm and 2.0 μm.

6. Semiconductor wafer (2) according to one of the preceding claims, whereby the concave surface (38), in cross-section, is axially symmetrical with respect to an axis of symmetry (A₂, A₃, A₄) and an apex (a₁, a₁′, a₁″) of the concave surface (38) is spaced between 40 μm/2 and 60 μm/2, or between 800 μm/2 and 1200 μm/2, from an edge of the depression holding the bonding material.

7. Semiconductor wafer (2) according to one of the preceding claims, whereby the at least one frame (34) has a rectangular basic shape.

8. Semiconductor wafer (2) according to one of the preceding claims, whereby the at least one frame (34) has at least one interruption (48, 48*), preferably at least one frame-shaped elevation (34), as the frame has interruptions (48, 48*) in each corner region of the frame-shaped elevations (34).

9. Semiconductor wafer (2) according to one of the preceding claims, whereby the at least one frame (34) has at least one recess (82a, 82b), preferably two opposing recesses (82a, 82b).

10. Semiconductor wafer (2) according to preceding claim 9, whereby the at least one recess (82a, 82b) has a polygonal basic shape.

11. Semiconductor wafer (2) according to one of the preceding claims, whereby the at least one frame (34) is dimensioned such that the concave surface (38) within the frame (34) is configured to contact multiple partial surfaces (22) as the underside of the component (20), preferably brought into full-contact with the surface, at least in the first approach for adapting a curvature to multiple flat partial surfaces of the underside of the component (20).

12. Semiconductor wafer (2) according to one of the preceding claims, whereby the frame (34) has a length (RI, R″, RI*) between 800 μm and 1.2 mm and a width (R_{w}, R_{w}″, R_{w}*) between 50 μm and 800 μm.

13. Semiconductor wafer (2) according to one of the preceding claims, whereby the frame (34, 34′, 34″) has a height (Rₕ, Rₕ′, Rₕ″) between 150.0 nm and 850.0 nm, preferably between 250.0 nm and 750.0 nm.

14. Semiconductor wafer (2) according to one of the preceding claims, whereby the at least one frame-shaped elevation (34) has a tether width (Rₜ, Rₜ″, Rₜ*) at least partially between 25.0 nm and 3000.0 nm, preferably between 65.0 nm and 2000.0 nm.

15. Semiconductor wafer (2) according to one of the preceding claims, whereby the semiconductor wafer (2) consists of a plurality of frames (34) into each of which bonding material (36, 39) is introduced, and whereby all surfaces (38) of the bonding material introduced into the frame-shaped elevations (34) are concave and are each adapted to contact the underside (22) of a component (20).

16. Semiconductor wafer (2) according to one of the preceding claims, whereby the frame (90a, 92a, 34′) is formed by exposing a depression (36a, 39a) by etching from the substrate of the semiconductor wafer in order to receive the bonding material (36, 39) within the effective frame and to form the at least partially concave surfaces (38, 38′).

17. Process for manufacturing a semiconductor wafer (2), the process consisting of the following steps
Provision of a semiconductor wafer with at least one functional frame (34, 34′, 34″, 34*) formed from a layer (31, 31′, 31″, 31*) of the semiconductor wafer or formed by a depression in a layer (31′) as its remaining edge region (34′, 90a, 92a); and
application of a bonding layer (37) serving as an adhesive layer to a surface of the layer (31) from which the functional frame (34, 34′) was formed,
whereby a region (36, 39) of the applied bonding layer (37) located within the functional frame at least partially forms a concave surface (38, 38′), preferably for contacting an underside (22) of a semiconductor component (20, 40).

18. Process according to claim 17, whereby the bonding layer (36, 39) within the functional frame (34, 34′) has a thickness of at least partially between 0.2 μm and 3.0 μm, preferably between 0.5 μm and 2.0 μm.

19. Process according to one of claims 17 to 18, whereby the concave surface (38, 38′), in cross-section is axially symmetrical with respect to an axis of symmetry (A₂, A₃, A₄) and an apex (a₁, a₁′) of the concave surface (38, 38′).

20. Process according to claim 17, whereby the bonding layer (37) consists of an organic material, preferably an epoxy material, polyimide, or adhesive.

21. Process according to claim 17, whereby a layer (54) acting as an adhesive is applied to an oxide (55) in the bonding material (36) within the functional frame (34); in particular, the oxide at least partially forms the concave surface in order to transfer it to the layer acting as an adhesive.

22. Process for manufacturing a semiconductor wafer (2), whereby the process consists of the following steps
Provision of a semiconductor wafer with at least one functional frame (34, 34′, 34″, 34*) formed from a first layer (31, 31′, 31″, 31*) of the semiconductor wafer, in particular by a recess (39a, 36a) formed therein; and
overpolishing of an applied second layer, whereby a region of the second layer within the functional frame (34) is formed with an at least partially concave surface (38, 38′) for contacting an underside (22) of a printed semiconductor component (20, 40).

23. Process according to claim 21, whereby the overpolishing involves chemical-mechanical polishing.

24. Process according to any one of claims 22 to 23, whereby the process further consists of: after overpolishing, application of a third layer (54) serving as an adhesive layer.

25. Process according to the preceding claim 24, whereby the third layer (54) serving as an adhesive layer has a thickness between 20.0 nm and 1000.0 nm, preferably between 50.0 nm and 500.0 nm.

26. Process according to one of claims 22 to 25, whereby material (39) of the overpolished second layer together with the adhesive layer (54) within the functional frame (34) has a thickness between 0.2 μm and 4.0 μm at least in sections, preferably between 0.5 μm and 2.5 μm.

27. Process according to one of claims 22 to 26, whereby the concave surface (38, 38′), in cross-section is axially symmetrical with respect to an axis of symmetry (A₂, A₃, A₄) and an apex (a₁, a₁′) of the concave surface (38, 38′).

28. Process according to claim 22, whereby the second layer consists of an oxide layer, preferably an oxide layer.

29. Transfer printing process, whereby the process has the following steps
Provision of a first semiconductor wafer (1) with semiconductor components (20) removable therefrom;
provision of a second semiconductor wafer (2);
transfer of at least one component (20, 40) from the first semiconductor wafer (1) to the second semiconductor wafer (2) in a transfer printing step;
whereby the at least one component (20) is transferred and printed 2: on a concave surface (38, 38′, 38″) within a functional frame (34, 34′, 34″, 34*) of the second semiconductor wafer (2).

30. Transfer printing process according to claim 29, whereby the process further consists of recognizing a position (x, y) of the at least one frame (34) on the semiconductor wafer (2) by means of recesses (82a, 82b) in the at least one frame (34).

31. Transfer printing process according to claim 29 or 30, whereby at least two components (20) are printed on the concave surface (38) within a functional frame (34, 34′).

32. The transfer printing process according to any one of claims 29 to 31, whereby a plurality of semiconductor devices are transferred from the first semiconductor wafer (1) to the second semiconductor wafer (2); in particular, one device (20, 40) at a time is transferred to a concave surface (38) within one of the functional frames (34, 34′).
